(19) United States
(12) Patent Application Publication
(10) Pub. No.: US 2026/0309937 A1
(43) Pub. Date: Oct. 8, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventor: Ting-Hsuan CHEN, Taichung City (TW)

(21) Appl. No.: 19/342,000

(22) Filed: Sep. 26, 2025

(30) Foreign Application Priority Data
Apr. 2, 2025 (TW) 114112852

(51) Int. Cl. G02B 6/42; H01L 23/00; H01L 25/00; H01L 25/16

(52) U.S. Cl. CPC G02B 6/4214; H10W 90/00; H10W 90/722

(57) ABSTRACT

An electronic package and a manufacturing method thereof are provided. The electronic package includes an electronic element, an electronic connector disposed on the electronic element, a photonic chip disposed on the electronic element, and a transmission component connected to the electronic connector. The electronic connector has at least one light-guiding member, and optical signals of the transmission component are reflected into a side surface of the photonic chip via the at least one light-guiding member to meet the requirements of low energy loss.

### BACKGROUND

### 1. Technical Field

The present disclosure relates to a semiconductor packaging technology, and more particularly, to an electronic package having a photonic chip and a manufacturing method thereof.

### 2. Description of Related Art

Currently, the application of optical communication is to configure 100 Gbps communication equipment in data centers or network operators, but this speed is gradually becoming insufficient. As a result, the industry has developed the co-packaged optics (CPO) structure to solve the problems of bandwidth density limitation and communication delay encountered in today's large volume of data transmission over the network by combining the key elements (i.e., optical elements and electronic elements) required for communication more tightly together.

FIG. 1A is a schematic cross-sectional view of a conventional semiconductor package 1a. As shown in FIG. 1A, the conventional semiconductor package 1a adopts CPO technology and includes: a substrate 10; an electronic chip 11 and a photonic chip (photonic IC) 12 disposed on the substrate 10 and electrically connected to the substrate 10; a packaging layer 13 encapsulating the photonic chip 12 and the electronic chip 11; an electronic connector 14a disposed above a top surface 12a of the photonic chip 12 and communicatively connected to the photonic chip 12; and a fiber array unit (FAU) 15 communicatively connected to the electronic connector 14a, wherein optical signals are transmitted to the electronic connector 14a via cables 150 of the fiber array unit 15, and then are transferred to the photonic chip 12.

When manufacturing the semiconductor package 1a, wafer-level specifications may be adopted so that the electronic connector 14a is disposed above the top surface 12a of the photonic chip 12 to obtain a higher production capacity. However, the optical signals of the fiber array unit 15 must pass through the internal grating structure above the top surface 12a of the photonic chip 12, resulting in signal energy loss.

Therefore, as shown in a semiconductor package 1b of FIG. 1B, the industry also has a design of disposing an electronic connector 14b on a side surface 12c of the photonic chip 12, so that the optical signals of the fiber array unit 15 can directly enter the photonic chip 12 without passing through the internal grating structure above the top surface 12a of the photonic chip 12, thereby avoiding the problem of signal energy loss.

However, when manufacturing the semiconductor package 1b, a unit form specification is required so that the electronic connector 14b can be connected to the side surface 12c of the photonic chip 12. Therefore, compared with the process using wafer-level specifications, the production capacity of the semiconductor package 1b is lower.

Therefore, overcoming the challenges of both production capacity and signal energy loss in the above-mentioned prior art has become a pressing issue that the industry urgently needs to resolve.

### SUMMARY

In view of the various deficiencies of the prior art, the present disclosure provides an electronic package, which comprises: an electronic element; an electronic connector disposed on the electronic element and having a first light-guiding member; a photonic chip disposed on the electronic element, wherein the first light-guiding member is located correspondingly to a side surface of the photonic chip; and a transmission component connected to the electronic connector.

The present disclosure also provides a method of manufacturing an electronic package, and the method comprises: providing a wafer-level substrate including a plurality of electronic elements; disposing an electronic connector having a first light-guiding member on each of the plurality of electronic elements; disposing a photonic chip on each of the plurality of electronic elements, wherein the first light-guiding member is located correspondingly on a side surface of the photonic chip to form a plurality of package modules; performing a singulation process on the wafer-level substrate to separate the plurality of package modules; and connecting a transmission component to the electronic connector.

In the aforementioned electronic package and method, the electronic element is an electronic integrated circuit chip.

In the aforementioned electronic package and method, the first light-guiding member is a reflector.

In the aforementioned electronic package and method, the transmission component is located on the side surface of the photonic chip.

In the aforementioned electronic package and method, the transmission component is a fiber array unit.

In the aforementioned electronic package and method, the transmission component has a set of cables. For example, the cables are optical fibers.

In the aforementioned electronic package and method, the transmission component has a second light-guiding member configured corresponding to the first light-guiding member. For example, the second light-guiding member is a reflector.

In the aforementioned electronic package and method, the present disclosure further comprises a carrying structure for carrying the photonic chip.

As can be seen from the above, in the electronic package and the manufacturing method thereof of the present disclosure, the electronic connector is designed with a first light-guiding member, so that optical signals of the transmission component are reflected and transmitted into the side surface of the photonic chip via the first light-guiding member, thereby meeting the requirement of low energy loss. At the same time, the electronic connector and the photonic chip are connected to the electronic element according to the wafer-level substrate specification to improve the production capacity. Therefore, the electronic package of the present disclosure can meet the requirements of both high production capacity and low signal energy loss without the drawbacks of the prior art.

### BRIEF DESCRIPTION OF THE DRAWINGS

FIG. 1A and FIG. 1B are schematic cross-sectional views of different conventional semiconductor packages.

FIG. 2A to FIG. 2E are schematic cross-sectional views illustrating a manufacturing method of an electronic package according to the present disclosure.

FIG. 3 is a schematic cross-sectional view according to another embodiment of FIG. 2E.

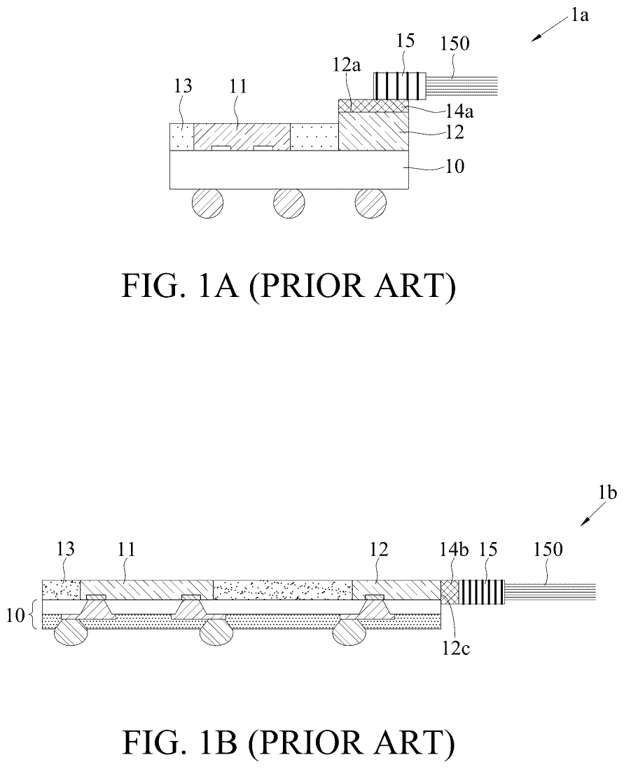

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “above,” “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

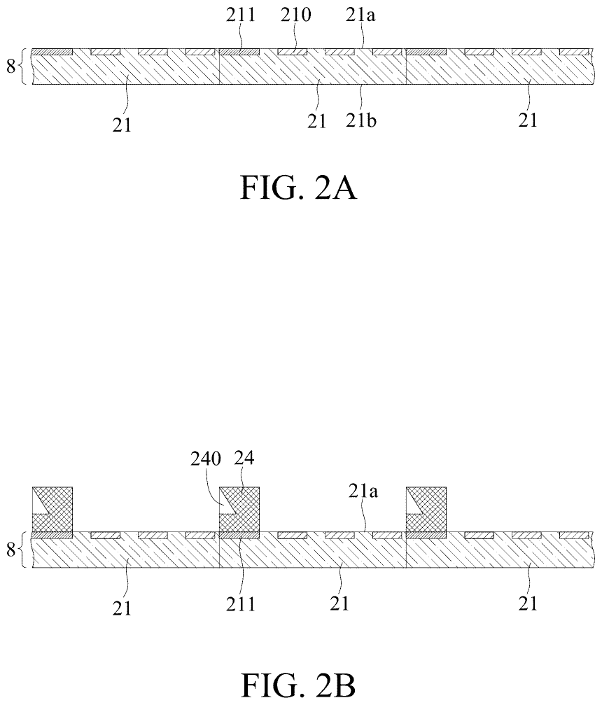

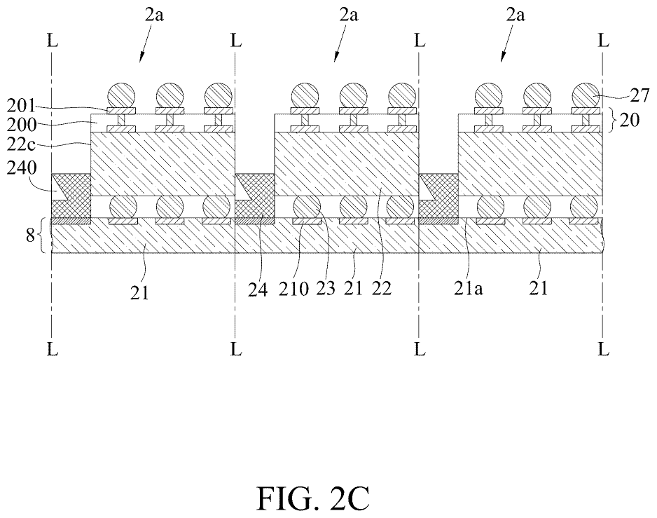

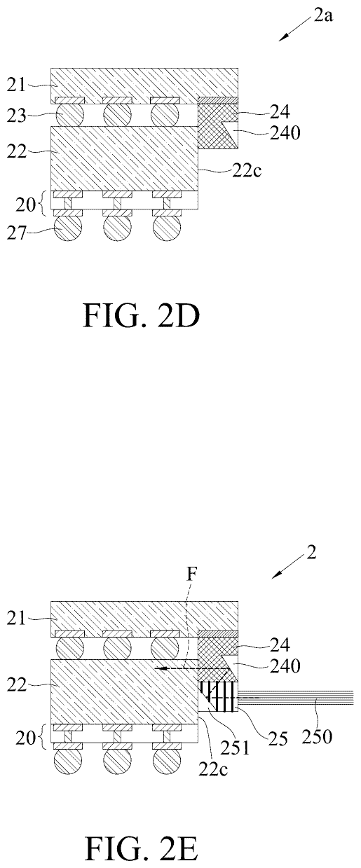

FIG. 2A to FIG. 2E are schematic cross-sectional views illustrating a manufacturing method of an electronic package 2 according to the present disclosure.

As shown in FIG. 2A, a wafer-level substrate 8 having a plurality of electronic elements 21 arranged in an array is provided. In one embodiment, each of the electronic elements 21 is a semiconductor chip, such as an electronic integrated circuit (EIC) chip. Each of the electronic elements 21 has an active surface 21a and an inactive surface 21b opposite to the active surface 21a, and the active surface 21a has a plurality of electrode pads 210 and electrical connection pads 211.

As shown in FIG. 2B, an electronic connector 24 having a first light-guiding member 240 is disposed on the active surface 21a of each of the electronic elements 21.

In one embodiment, the electronic connector 24 is electrically connected to the electrical connection pad 211, and the first light-guiding member 240 is a reflector.

As shown in FIG. 2C, a photonic chip 22 is disposed on the active surface 21a of each of the electronic elements 21 to form a plurality of package modules 2a, and the first light-guiding member 240 is correspondingly located on a side surface 22c of the photonic chip 22.

In one embodiment, the electronic connector 24 is located on the side surface 22c of the photonic chip 22.

Moreover, the photonic chip 22 can be bonded to the electrode pads 210 of the electronic element 21 via a plurality of conductive bumps 23, so that the photonic chip 22 is electrically connected to the electronic element 21. For example, the conductive bumps 23 are copper pillars, solder bumps, or other metal materials, but the present disclosure is not limited to as such.

Furthermore, a circuit structure 20 may be formed on the photonic chip 22, and a plurality of conductive elements 27 such as solder balls may be bonded to the circuit structure 20.

In addition, the circuit structure 20 includes at least one insulating layer 200 and at least one circuit layer 201 bonded to the insulating layer 200 and electrically connected to the photonic chip 22, such as a fan-out type redistribution layer (RDL). For example, the circuit layer 201 is made of copper. The insulating layer 200 is made of a dielectric material such as polybenzoxazole (PBO), polyimide (PI), prepreg (PP), or the like, or is made of a solder-resist material such as solder mask, ink, or the like.

As shown in FIG. 2D, the substrate 8 is subjected to a singulation process along cutting paths L shown in FIG. 2C to separate the package modules 2a, so that each of the package modules 2a follows a unit form specification.

As shown in FIG. 2E, a transmission component 25 is connected to the electronic connector 24, so that the transmission component 25 is located on the side surface 22c of the photonic chip 22.

In one embodiment, the transmission component 25 is a fiber array unit (FAU) and has a set of cables 250 and a second light-guiding member 251 corresponding to the first light-guiding member 240. For example, the second light-guiding member 251 may be a reflector and is communicatively connected to the cables 250 and the first light-guiding member 240, and the cables 250 are optical fibers. Accordingly, optical signals are transmitted to the second light-guiding member 251 via the cables 250 and then are reflected to the first light-guiding member 240 to be reflected to the side surface 22c of the photonic chip 22 (see, for example, a transmission path F), so that the optical signals enter the photonic chip 22 from the side surface 22c of the photonic chip 22.

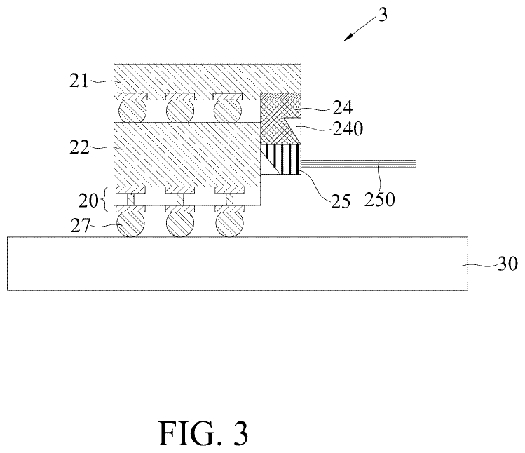

In other embodiments, such as an electronic package 3 shown in FIG. 3, the photonic chip 22 can be disposed on a carrying structure 30 via the conductive elements 27.

The carrying structure 30 is a substrate for carrying chips. For example, the carrying structure 30 is a circuit structure with a core layer, a circuit structure without a core layer (a coreless circuit structure), a through-silicon interposer (TSI) with through-silicon vias (TSVs), a lead frame, a wafer, or other board with metal routings, but the present disclosure is not limited to as such.

Therefore, in the electronic package 2, 3 of the present disclosure, the first light-guiding member 240 of the electronic connector 24 is used to generate edge coupling on the side surface 22c of the photonic chip 22. Thus, optical signals are reflected and transmitted via the first light-guiding member 240 to the side surface 22c of the photonic chip 22, so as to directly enter the photonic chip 22 without passing through the internal grating structure above the photonic chip 22, thereby reducing energy loss. Therefore, the electronic package 2, 3 of the present disclosure can effectively avoid the problem of signal energy loss. On the other hand, in the manufacturing method of the present disclosure, by virtue of the specifications of the wafer-level substrate 8, the electronic connector 24 and the photonic chip 22 can be connected to a plurality of electronic elements 21 of the whole layout, and then the singulation process is performed. Accordingly, the manufacturing method of the present disclosure can improve production capacity. It can be seen that the electronic package 2, 3 of the present disclosure can meet the requirements of both high production capacity and low signal energy loss.

Additionally, the electronic package 2, 3 of the present disclosure can be manufactured using existing semiconductor packaging processes without the need to develop special processes or purchase special equipment, thereby significantly reducing product production costs and meeting high feasibility requirements.

The present disclosure further provides an electronic package 2, 3, which comprises: an electronic element 21, an electronic connector 24 having a first light-guiding member 240, a photonic chip 22, and a transmission component 25.

The electronic connector 24 is disposed on the electronic element 21.

The photonic chip 22 is disposed on the electronic element 21, so that the first light-guiding member 240 is located corresponding to a side surface 22c of the photonic chip 22.

The transmission component 25 is connected to the electronic connector 24.

In one embodiment, the electronic package 3 further comprises a carrying structure 30 on which the photonic chip 22 is disposed.

In one embodiment, the electronic element 21 is an electronic integrated circuit chip.

In one embodiment, the first light-guiding member 240 is a reflector.

In one embodiment, the transmission component 25 is located on the side surface 22c of the photonic chip 22.

In one embodiment, the transmission component 25 is a fiber array unit.

In one embodiment, the transmission component 25 has a set of cables 250. For example, the cables 250 are optical fibers.

In one embodiment, the transmission component 25 has a second light-guiding member 251 configured to correspond to the first light-guiding member 240. For example, the second light-guiding member 251 is a reflector.

To sum up, in the electronic package and the manufacturing method thereof of the present disclosure, the electronic connector is designed with a first light-guiding member, so that optical signals of the transmission component are reflected and transmitted into the side surface of the photonic chip via the first light-guiding member, thereby meeting the requirement of low energy loss. At the same time, the electronic connector and the photonic chip are connected to the electronic element according to the wafer-level substrate specification to improve the production capacity. Therefore, the electronic package of the present disclosure can meet the requirements of both high production capacity and low signal energy loss.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
an electronic element;
an electronic connector disposed on the electronic element and having a first light-guiding member;
a photonic chip disposed on the electronic element, wherein the first light-guiding member is located correspondingly to a side surface of the photonic chip; and
a transmission component connected to the electronic connector.

2. The electronic package of claim 1, further comprising: a carrying structure for carrying the photonic chip.

3. The electronic package of claim 2, wherein the electronic element is an electronic integrated circuit chip.

4. The electronic package of claim 2, wherein the first light-guiding member is a reflector.

5. The electronic package of claim 2, wherein the transmission component is located on the side surface of the photonic chip.

6. The electronic package of claim 2, wherein the transmission component is a fiber array unit.

7. The electronic package of claim 2, wherein the transmission component has a set of cables.

8. The electronic package of claim 7, wherein the cables are optical fibers.

9. The electronic package of claim 2, wherein the transmission component has a second light-guiding member configured corresponding to the first light-guiding member.

10. The electronic package of claim 9, wherein the second light-guiding member is a reflector.

11. The electronic package of claim 1, wherein the electronic element is an electronic integrated circuit chip.

12. The electronic package of claim 1, wherein the first light-guiding member is a reflector.

13. The electronic package of claim 1, wherein the transmission component is located on the side surface of the photonic chip.

14. The electronic package of claim 1, wherein the transmission component is a fiber array unit.

15. The electronic package of claim 1, wherein the transmission component has a set of cables.

16. The electronic package of claim 15, wherein the cables are optical fibers.

17. The electronic package of claim 1, wherein the transmission component has a second light-guiding member configured corresponding to the first light-guiding member.

18. The electronic package of claim 17, wherein the second light-guiding member is a reflector.

19. A method of manufacturing an electronic package, comprising:
providing a wafer-level substrate including a plurality of electronic elements;
disposing an electronic connector having a first light-guiding member on each of the plurality of electronic elements;
disposing a photonic chip on each of the plurality of electronic elements, wherein the first light-guiding member is located correspondingly on a side surface of the photonic chip to form a plurality of package modules;
performing a singulation process on the wafer-level substrate to separate the plurality of package modules; and
connecting a transmission component to the electronic connector.

20. The method of claim 19, wherein each of the plurality of electronic elements is an electronic integrated circuit chip.

21. The method of claim 19, wherein the first light-guiding member is a reflector.

22. The method of claim 19, wherein the transmission component is located on the side surface of the photonic chip.

23. The method of claim 19, wherein the transmission component is a fiber array unit.

24. The method of claim 19, wherein the transmission component has a set of cables.

25. The method of claim 24, wherein the cables are optical fibers.

26. The method of claim 19, wherein the transmission component has a second light-guiding member configured corresponding to the first light-guiding member.

27. The method of claim 26, wherein the second light-guiding member is a reflector.

28. The method of claim 26, further comprising: disposing the photonic chip having the electronic element, the electronic connector and the transmission component on a carrying structure.
